(19) United States
(12) Patent Application Publication
(10) Pub. No.: US 2006/0268532 A1
(43) Pub. Date: Nov. 30, 2006

(54) Multi-function peripheral with improved ground structure

(75) Inventor: In-Gu Kwak, Yongin-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/357,041

(22) Filed: Feb. 21, 2006

(30) Foreign Application Priority Data
May 26, 2005 (KR) 2005-0044465

(51) Int. Cl. H05K 1/11

(52) U.S. Cl. 361/792

(57) ABSTRACT

A multi-function peripheral is provided. The multi-function peripheral comprises an image printing unit, an image scanning unit which is openably provided on the image printing unit and scans an image, and a ground unit which is electrically disconnected or connected by opening or shutting the image scanning unit from the image printing unit and delivers electrical noise generated from the image scanning unit to the image print unit via a shortened conductive path.

### PRIORITY

This application claims the benefit under 35 U.S.C. § 119(a) of Korean Patent Application No. 2005-0044465, filed on May 26, 2005, in the Korean Intellectual Property Office, the entire disclosure of which is hereby incorporated by reference.

### BACKGROUND OF THE INVENTION

1. Field of the Invention

The present invention relates to a multi-function peripheral. More particularly, the present invention relates to a multi-function peripheral having a ground structure for preventing electrical noise delivered from an image scanning unit to an image printing unit from being radiated into space.

2. Description of the Related Art

In general, an image forming apparatus receives a digital image signal, forms an electrostatic latent image on a photosensitive medium by an exposing unit such as a laser scanning unit (LSU), develops the electrostatic latent image using a toner to form a toner image, transfers the toner image onto a recording medium, and fixes the toner image onto the recording medium with high temperature and high pressure, thereby forming a desired image.

Image forming apparatuses are typically classified into wet type and dry type image forming apparatuses according to the states of the toner and carrier. A wet type image forming apparatus is also classified into an image forming apparatus having a one-phase developer and an image forming apparatus having a two-phase developer.

While the one-phase developer supplies only toner to form an image, the two-phase developer supplies a carrier mixed with toner to form an image.

In a one-phase developer, the toner is supplied to the photosensitive medium to form the toner image and then the toner remaining on the surface of the photosensitive medium is removed by a cleaning blade and collected by a collecting device such that the toner can be reused.

In a two-phase developer, the carrier is not supplied to the photosensitive medium and is collected, the toner is supplied to the photosensitive medium to form the toner image, and then the toner remaining on the surface of the photosensitive medium is removed by a cleaning blade and collected by a collecting device such that the toner can be reused.

Recently, multi-function peripherals that incorporate a scanning (image reading) function and a printing function in one combined unit have been widely used. In this multi function peripheral, an image scanning unit is disposed above an image printing unit and reads and inputs an image from a document. The image printing unit receives a digital image signal corresponding to the image input from the image scanning unit and prints a toner image.

This multi function peripheral is classified into a perfectly separating type peripheral in which the image scanning unit and the image printing unit are perfectly separated from each other, and an opening-and-shutting type peripheral which the image scanning unit and the image printing unit are connected to each other so that the image scanning unit can be open or shut from the image printing unit.

In the image scanning unit, a scan module linearly and reciprocally moves by a driving motor and reads the image on the document. At this time, electromagnetic noise is generated by the driving motor. This electromagnetic noise represents a fault of the system and thus adversely affects the multi function peripheral.

Accordingly, various methods for removing electromagnetic noise have been researched. Generally, the image scanning unit and the image printing unit are electrically connected to each other using a ground cable or wire so that electromagnetic noise generated by the driving motor is delivered to a main frame of the peripheral. Since the main frame is also grounded, the electromagnetic noise delivered from the image scanning unit is extinguished through the main frame.

However, since the ground cable or wire has a predetermined length, an impedance value increases depending on the length of the ground cable or wire and thus some electromagnetic noise is not delivered to the main frame and may be radiated into space.

As the impedance value due to an inductance component of the ground cable increases, the electromagnetic noise increases. That is, the electromagnetic noise generated by the driving motor contains a frequency component comprising a wide band of several MHz to 200 MHz. In order to extinguish the electromagnetic noise, a ground structure having a low impedance characteristic in the band of several MHz to 200 MHz is required.

However, in the case of the open-and-shut type multi-function peripherals, the length of the ground cable is long and the impedance of the ground cable rapidly increases in the band of 10 MHz and higher. Accordingly, the ground cable can not serve as an electromagnetic noise delivering path and the electromagnetic noise is radiated to space.

### SUMMARY OF THE INVENTION

The present invention provides a multi-function peripheral having a ground structure for reducing impedance so that electromagnetic noise can be smoothly delivered from an image scanning unit to an image printing unit.

According to an aspect of the present invention, there is provided a multi-function peripheral comprising an image printing unit; an image scanning unit which is openably provided on the image printing unit and is configured to scan an image; and a ground unit which is electrically coupled by opening or shutting the image scanning unit relative the image printing unit and delivers electrical noise generated from the image scanning unit to the image print unit.

### BRIEF DESCRIPTION OF THE DRAWINGS

The above and other features and advantages of the present invention will become more apparent by describing in detail exemplary embodiments thereof with reference to the accompanying drawings, in which:

FIG. 1 is a perspective view of a multi function peripheral having a ground unit according to an exemplary embodiment of the present invention;

FIG. 2 is a cross-sectional view schematically illustrating a structure of the multi function peripheral shown in FIG. 1; and

FIG. 3 is a partial perspective view illustrating an example of the ground unit according to an exemplary embodiment of the present invention.

Throughout the drawings, like reference numbers should be understood to refer to like elements, features, and structures.

### DETAILED DESCRIPTION OF EXEMPLARY EMBODIMENTS

The matters exemplified in this description are provided to assist in a comprehensive understanding of various exemplary embodiments of the present invention disclosed with reference to the accompanying figures. Accordingly, those of ordinary skill in the art will recognize that various changes and modifications of the exemplary embodiments described herein can be made without departing from the scope and spirit of the claimed invention. Descriptions of well-known functions and constructions are omitted for clarity and conciseness.

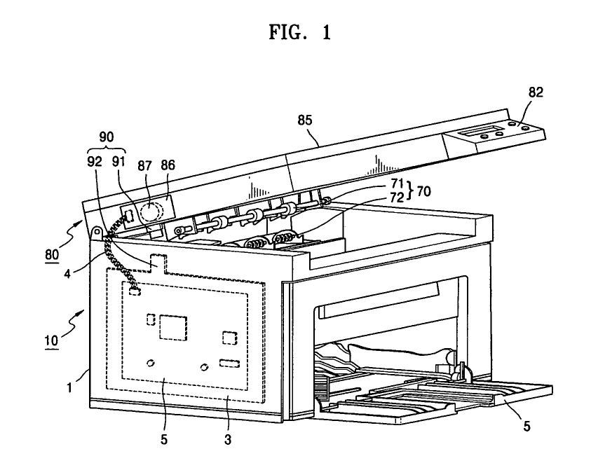

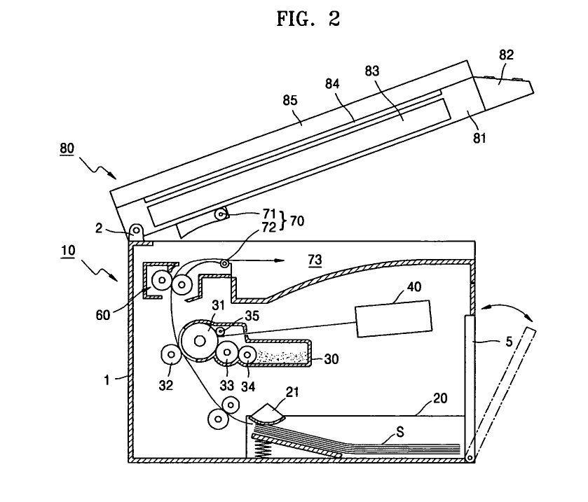

Referring to FIGS. 1 and 2, a multi-function peripheral comprises an image printing unit 10, an image scanning unit 80, and a ground unit 90.

The image scanning unit 80 is openably coupled to the image printing unit 10. A discharge tray 73 for loading a recording medium S on which an image is formed is provided between the image printing unit 10 and the image scanning unit 80.

The image printing unit 10 prints a desired image and comprises a cassette 20, a developing unit 30, a transfer roller 32, a fixing unit 60, and a discharging unit 70.

The cassette 20 is detachably provided at a lower side of a main body 1 and loads a plurality of the recording media S. A pickup roller 21 for picking up the recording medium S one by one is provided above the cassette 20. The recording medium S picked up by the pickup roller 21 is subjected to a transferring process and a fixing process while being conveyed along a conveying path, shown in FIG. 2 by the direction of the arrow, and then loaded on the discharging tray 73 through the discharging unit 70.

A front cover 5 is openably coupled to a front surface of the main body 1. The front cover 5 comprises a portion of the main body 1 and opens so that the cassette 20 can be attached or detached to/from the main body 1.

The developing unit 30 forms an electrostatic latent image corresponding to a digital image signal by light irradiated from an exposing unit 40, such as a laser scanning unit (LSU) to a surface charged to a predetermined potential, and comprises a photosensitive drum 31, a developing roller 33, a supplying roller 34, and a charging roller 35.

The photosensitive drum 31 is provided to face the transfer roller 32 through the recording medium S. The recording medium S passes between the photosensitive drum 31 and the transfer roller 32. Toner, which is supplied to the electrostatic latent image formed on the photosensitive drum 31, to form a toner image is stored in the developing unit 30.

The developing roller 33 develops the electrostatic latent image formed on the photosensitive medium 31 using the toner. The supplying roller 34 rotates while in contact with the developing roller 33 to adhere the toner (nonmagnetic toner) onto the developing roller 33 by triboelectrification. The charging roller 35 charges the outer peripheral surface of the photosensitive drum 31 to a predetermined potential.

The fixing unit 60 applies heat and pressure to the toner image transferred onto the recording medium S passing between the photosensitive drum 31 and transfer roller 32 to fix the toner image onto the recording medium S.

The discharging unit 70 comprises a pair of discharging rollers 71 and 72 and discharges the recording medium S onto which the toner image has been fixed by fixing unit 60 to the discharging tray 73.

The discharging roller 71 is rotatably provided on a lower surface of the image scanning unit 80, and the discharging roller 72 is rotatably provided above the image printing unit 10. Accordingly, when the image scanning unit 80 opens, the discharging roller 71 moves upwardly together with the image scanning unit 80 and is thus separated from the discharging roller 72.

The image scanning unit 80 is provided above the image printing unit 10 so that it can open or shut by a hinge 2, which can be a rotary shaft, and scans an image by irradiating light onto a document (not shown). The image scanning unit 80 comprises a scanning frame 81 and a scan cover 85, which is openably provided on the scanning frame 81.

A glass plate 84 is provided at an upper side of the scanning frame 81, and a scan module 83 for irradiating the light onto the document laid on the glass plate 84 and inputting the image is provided below the glass plate 84 such that it can linearly and reciprocally move. The scan module 83 irradiates the light onto the document while reciprocally moving by a driving motor 87 and scans the image on the document. An operating panel 82 for controlling the multi-function peripheral can be provided on a front surface of the scanning frame 81.

The scan cover 85 covers the document laid on the glass plate 84 so that the light irradiated from the scan module 83 cannot be radiated to the outside, thereby allowing the scan module 83 to stably scan the image.

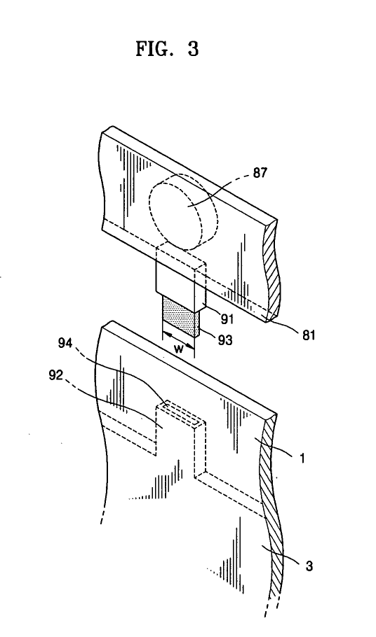

The ground unit 90 allows electromagnetic noise generated at the image scanning unit 80 to flow into the image printing unit 10 and prevents the electromagnetic noise from being radiated into space. The ground unit 90 comprises a first ground unit 91 and a second ground unit 92, as shown in FIG. 3.

The first ground unit 91 is downwardly protruded from a driving motor frame 86 for supporting the driving motor 87 and is made of conductive material. The driving motor frame 86 is provided in the scanning frame 81 and made of conductive material. Accordingly, the electrical noise generated at the driving motor 87 can flow into the first ground unit 91 through the driving motor frame 86.

The second ground unit 92 is upwardly protruded from a main frame 3 provided in the main body 1 and made of conductive material. A main board 5 for controlling the image printing unit 10 and the image scanning unit 80 is provided in the main frame 3.

It is preferable that the first ground unit 91 and the second ground unit 92 can be electrically coupled to each other.

According to an aspect of the present invention, the first ground unit 91 is inserted into the second ground unit 92. That is, the first ground unit 91 has a protrusion 93, the second ground unit 92 has a receiving unit 94, and the protrusion 93 is inserted into the receiving unit 94 to electrically connect the first ground unit 91 and the second ground unit 92. According to the present invention, the ground unit 90 for connecting the driving motor frame 86 and the main frame 3 has a small length and a large width, W, and thus electrical noise can be delivered from the driving motor frame 86 to the main frame 3.

The present invention is not limited to the aforementioned grounding unit 90 and various modified examples can be applied as long as electrical connection can be accomplished and conditions such as length and width can be satisfied.

As mentioned above, the multi-function peripheral according to the present invention comprises a ground unit which is disconnected or connected by opening or shutting the image scanning unit from the image printing unit to reduce the impedance and thus prevents the electromagnetic noise from being radiated to space.

While the present invention has been particularly shown and described with reference to certain exemplary embodiments thereof, it will be understood by those of ordinary skill in the art that various changes in form and detail may be made therein without departing from the spirit and scope of the present invention as defined by the following claims.

What is claimed is:

1. A multi-function peripheral comprising:
an image printing unit;
an image scanning unit which is openably coupled to the image printing unit and configured to scan an image; and
a ground unit that is electrically disconnected or connected by opening or shutting the image scanning unit from the image printing unit and delivers electrical noise generated from the image scanning unit to the image printing unit.

2. The multi-function peripheral according to claim 1, wherein the ground unit comprises:
a first ground unit that is provided in the image scanning unit and connected to a driving motor frame in which a driving motor for driving a scan module is provided; and
a second ground unit that is provided in the image printing unit and connected to a main frame so as to be releasably electrically connected to the first ground unit.

3. The multi-function peripheral according to claim 2, wherein the first ground unit comprises a downward protrusion and the second ground unit comprises an upward protrusion forming a receiving unit that is adapted to mechanically couple with the first ground unit and form an electrical connection.

4. The multi-function peripheral according to claim 3, wherein the first ground unit inserts into the receiving unit to electrically connect the first ground unit and the second ground unit.

5. A method of forming a multi-function peripheral, the method comprising:
forming a first ground unit comprising a downward protrusion on an image scanning unit; and
forming a second ground unit comprising an upward protrusion on an image printing unit,
wherein the image scanning unit is openably coupled to the image printing unit and the first and second ground units electrically connect and disconnect by closing and opening the image scanning unit relative to the image printing unit so that electrical noise generated by the image scanning unit can be delivered to the image printing unit.

6. The method of claim 5 further comprising:
providing electrical coupling between the first and second ground units, wherein the first ground unit comprises a downward protrusion and the second ground unit comprises an upward protrusion forming a receiving unit that is adapted to mechanically couple with the first ground unit by inserting the downward protrusion into the receiving unit.
